(19) United States
(12) Patent Application Publication
(10) Pub. No.: US 2016/0007501 A1
(43) Pub. Date: Jan. 7, 2016

(54) COOLING SYSTEM AND ELECTRONIC DEVICE

(71) Applicant: FUJITSU LIMITED, Kawasaki-shi (JP)

(72) Inventors: TERU NAKANISHI, Isehara (JP); Nobuyuki HAYASHI, Yokohama (JP); Yasuhiro Yoneda, Machida (JP)

(21) Appl. No.: 14/857,415

(22) Filed: Sep. 17, 2015

Related U.S. Application Data
(63) Continuation of application No. PCT/JP2013/058390, filed on Mar. 22, 2013.

(51) Int. Cl. H05K 7/20

(52) U.S. Cl. CPC H05K 7/20254

(57) ABSTRACT

An object of technology disclosed herein is to improve cooling performance for plural heat generating bodies.

A cooling system includes a heat dissipating section, plural heat receiving sections, and a bypass section. The heat dissipation section dissipates heat from a coolant by exchanging heat with an external fluid. The plural heat receiving sections are connected in parallel to the heat dissipating section, and heat generated by respective heat generating bodies is absorbed by the coolant. The bypass section couples at least one of the heat receiving sections out of the plurality of heat receiving sections to another heat receiving section.

### CROSS-REFERENCE TO RELATED APPLICATION

This application is a continuation application of International Application No. PCT/JP2013/058390, filed on Mar. 22, 2013, the disclosure of which is incorporated herein by reference in its entirety.

### FIELD

Technology disclosed herein is related to a cooling system and an electronic device.

### BACKGROUND

Known cooling systems are provided with a heat dissipation section that dissipates heat from a coolant by exchanging heat with an external fluid, and a heat receiving section that is connected to the heat dissipation section and absorbs heat in the coolant that was generated by a heat generating body. In such cooling systems, the heat generating body is cooled by coolant that is circulating between the heat receiving section and the heat dissipation section repeatedly receiving heat and dissipating heat.

### RELATED PATENT DOCUMENTS

Japanese Laid-Open Patent Publication No. 2002-168547

Japanese Laid-Open Patent Publication No. 2012-42115

In such cooling systems, respective heat receiving sections are sometimes employed for each of plural heat generating bodies, and the plural heat receiving sections are connected in series to a single heat dissipating section.

However, when plural heat receiving sections are connected in series to a single heat dissipation section in this manner, the coolant is supplied to the heat receiving sections at the downstream side via the heat receiving sections at the upstream side. Coolant supplied to the heat receiving sections at the downstream side therefore includes heat obtained from the heat receiving sections at the upstream side, and so there is a concern that cooling performance is reduced for the heat receiving sections at the downstream side.

It is conceivable to connect the plural heat receiving sections to the heat dissipation section in parallel in order to make the temperatures of coolant supplied to the plural heat receiving sections equivalent to one another. However, in cases in which plural heat receiving sections are connected in parallel to a heat dissipation section in this manner, when the amounts of heat generated by the plural heat generating bodies are different to each other, differences arise in the internal pressure of the plural heat receiving sections due to the different temperatures of the plural heat receiving sections.

When differences arise in the internal pressure of the plural heat receiving sections in this manner, coolant is more easily supplied to the heat receiving sections having low internal pressure, and coolant is less easily supplied to the heat receiving sections having high internal pressure. Thus when the amounts of heat generated by plural heat generating bodies differs, differences arise in the amount of coolant supplied to the plural heat receiving sections, and there is therefore a concern that the cooling performance is reduced for plural heat generating bodies.

According to an aspect of the embodiments, a cooling system includes: a heat dissipating section that dissipates heat from a coolant by exchanging heat with an external fluid; plural heat receiving sections that are connected in parallel to the heat dissipating section, and in which heat generated by respective heat generating bodies is absorbed by the coolant; and a bypass section that couples at least one of the heat receiving sections out of the plural heat receiving sections to another heat receiving section.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view of an electronic device installed with a cooling system according to a first exemplary embodiment.

FIG. 2 is a plan view of a cooling system according to the first exemplary embodiment.

FIG. 3 is a plan view of a cooling system according to a second exemplary embodiment.

FIG. 4 is a side view of the cooling system illustrated in FIG. 3.

FIG. 5 is a plan view of a cooling system according to a third exemplary embodiment.

FIG. 6 is a plan view of a cooling system of a fourth exemplary embodiment.

FIG. 7 is a plan view of a cooling system of a fifth exemplary embodiment.

FIG. 8 is a cross-section plan view of an evaporator illustrated in FIG. 7.

FIG. 9 is a plan view of a cooling system according to a sixth exemplary embodiment.

### DESCRIPTION OF EMBODIMENTS

An object of an aspect of technology disclosed herein is to improve cooling performance for plural heat generating bodies.

### First Exemplary Embodiment

Firstly, explanation follows regarding a first exemplary embodiment of technology disclosed herein.

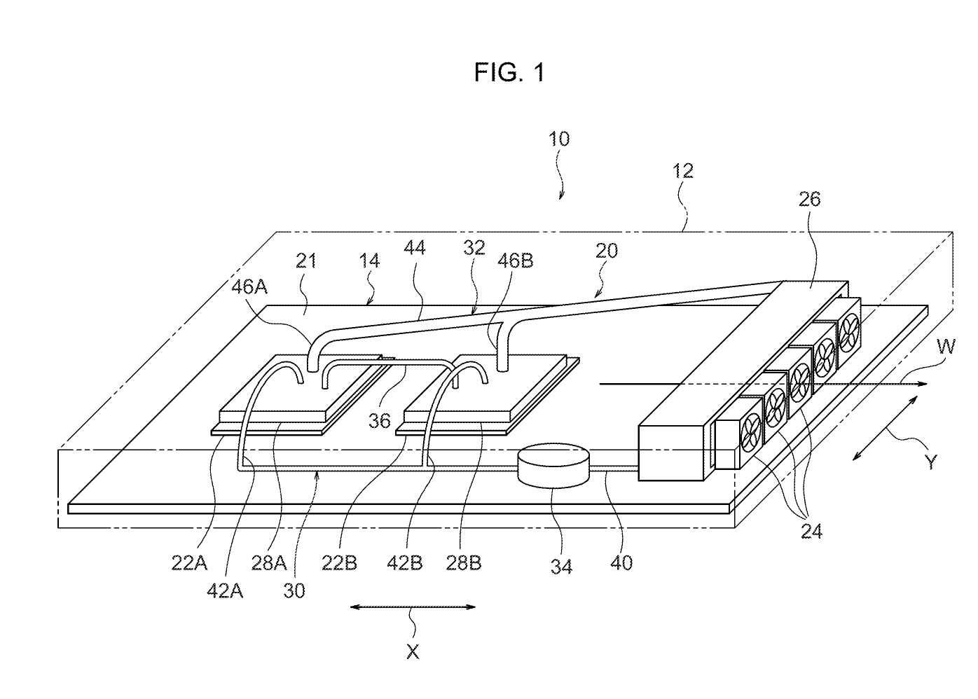

As illustrated in FIG. 1, an electronic device 10 includes a rack 12, a circuit unit 14, and a cooling system 20. The circuit unit 14 and the cooling system 20 are housed in the flatted box-shaped rack 12.

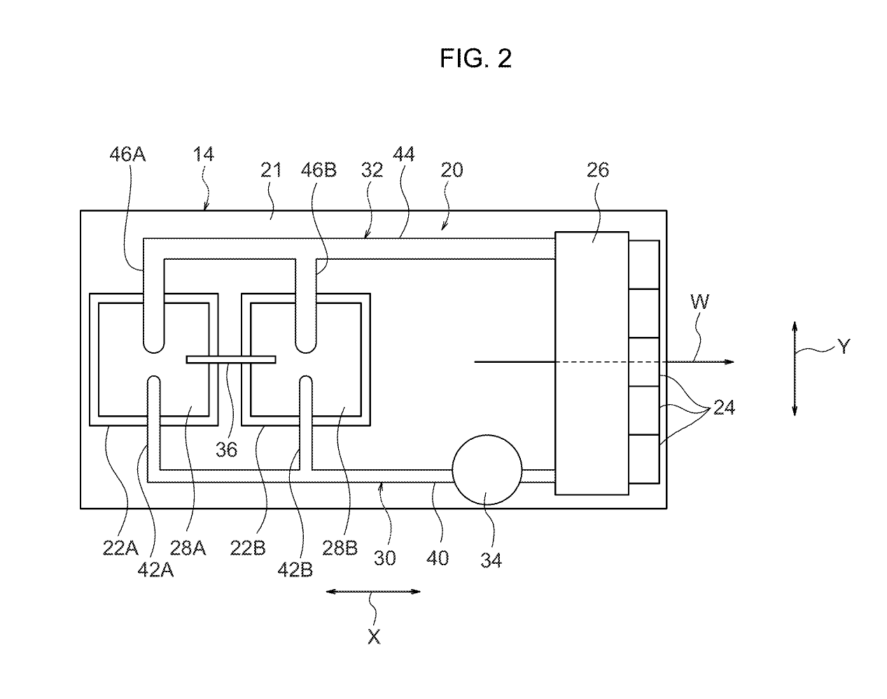

As illustrated in FIG. 2, the circuit unit 14 includes a rectangular substrate 21, as viewed in plan view. Plural heat generating bodies 22A, 22B are mounted on the substrate 21. The number of heat generating bodies in the first exemplary embodiment is two, as an example. The plural heat generating body 22A, 22B are components that generate heat such as, for example, a central processing unit (CPU) or a power source module. The plural heat generating bodies 22A, 22B are disposed in a row along a specific direction on the substrate 21 (in an x-direction, which is the length direction of the substrate 21, as an example).

The cooling system 20 includes plural fans 24, a condenser 26, a pair of evaporators 28A, 28B, a feed pipe 30, a return pipe 32, a circulation pump 34, and a bypass pipe 36.

The plural fans 24 are provided on the substrate 21. The plural fans 24 are in a row along a direction (a Y-direction) orthogonal to the direction in which the plural heat generating bodies 22A, 22B are in a row, as viewed in plan view of the substrate 21. Driving the plural fans generates a cooling airflow W flowing along the row direction of the plural heat generating bodies 22A, 22B described above.

The condenser 26 is formed substantially box shaped, and the direction in which the plural fans 24 are disposed in a row is the length direction of the condenser 26. The condenser 26 is provided with the plural fans 24 adjacent to each other, and is provided between the plural heat generating bodies 22A, 22B and the plural fans 24. The condenser 26 includes a pipe to which vaporized coolant is supplied, and the pipe is provided with plural heat dissipation fans. Air ducts are formed between the plural heat dissipation fans, piercing through in the direction in which the cooling airflow W flows. When vaporized coolant (hydraulic fluid in the gaseous phase) is supplied to the condenser 26, the vaporized coolant is condensed by exchanging heat with the cooling airflow W. The condenser 26 is an example of a heat dissipation section that dissipates heat from the coolant by exchanging heat with an external fluid, and the cooling airflow W is an example of an external fluid.

The pair of evaporators 28A, 28B are each an example of a heat receiving section (heat receiving device) that absorbs heat generated in a heat generating body, and are mutually independent. The pair of evaporators 28A, 28B are fixed onto the plural heat generating bodies 22A, 22B, respectively, and are in thermal contact with the plural heat generating bodies 22A, 22B, respectively. Spaces are provided inside the pair of evaporators 28A, 28B for supplying the condensed coolant into. The pair of evaporators 28A, 28B are configured similarly to each other. The coolant in each of the respective evaporators 28A, 28B is vaporized by heat generated by the heat generating bodies 22A, 22B when liquefied coolant (the hydraulic fluid in the liquid phase) is supplied to respective evaporators 28A, 28B.

The feed pipe 30 includes a feed pipe main body 40, and a pair of connecting pipes 42A, 42B. One end of the feed pipe main body 40 is connected to an outlet of the condenser 26. One end of each of the pair of connecting pipes 42A, 42B is connected to the other end side of the feed pipe main body 40. The other ends of the pair of connecting pipes 42A, 42B are connected to the top wall sections of the respective evaporators 28A, 28B.

The return pipe 32 includes a return pipe main body 44, and a pair of connecting pipes 46A, 46B. One end of the return pipe main body 44 is connected to an inlet of the condenser 26. One end of each of the pair of connecting pipes 46A, 46B is connected to the other end side of the return pipe main body 44. The other ends of the pair of connecting pipes 46A, 46B are connected to the top wall sections of the respective evaporators 28A, 28B. The feed pipe 30 and the return pipe 32 connect the pair of evaporators 28A, 28B to the condenser 26 in parallel.

The circulation pump 34 is provided on the feed pipe main body 40. Driving the circulation pump 34 supplies coolant from the condenser 26 to the pair of evaporators 28A, 28B through the feed pipe 30, and supplies the coolant from the pair of evaporators 28A, 28B to the condenser 26 through the return pipe 32.

The bypass pipe 36 is an example of a bypass section. Both ends of the bypass pipe 36 are connected to top wall sections of a pair of evaporators 28A, 28B, respectively. A space is provided inside the pair of evaporators 28A, 28B, and the spaces are placed in communication with each other by the bypass pipe 36.

Explanation next follows regarding operation and advantageous effects of the first exemplary embodiment.

In the cooling system 20 according to the first exemplary embodiment, driving the plural fans 24 generates a flow of the cooling airflow W in the row direction of the plural heat generating bodies 22A, 22B, and supplies the cooling airflow W to the plural heat generating bodies 22A, 22B and the condenser 26. Moreover, driving the circulation pump 34 supplies coolant from the condenser 26 to the pair of evaporators 28A, 28B through the feed pipe 30. Coolant is vaporized in the respective evaporators 28A, 28B by heat generated by the heat generating bodies 22A, 22B (the coolant receives heat). Moreover, driving the circulation pump 34 supplies coolant from the pair of evaporators 28A, 28B to the condenser 26 through the return pipe 32. Coolant is condensed in the condenser 26 by exchanging heat with the cooling airflow W (the coolant dissipates heat).

The amounts of heat generated by the plural heat generating bodies 22A, 22B may differ according to the driving conditions of the plural heat generating bodies 22A, 22B. When the amounts of heat generated by the plural heat generating bodies 22A, 22B differs, a difference arises in the internal pressures of the plural evaporators 28A, 28B due to a difference in the temperatures of the plural evaporators 28A, 28B

However, in the cooling system 20 according to the first exemplary embodiment, the pair of evaporators 28A, 28B are coupled together by the bypass pipe 36. Thus, although a difference may arise in the internal pressures of the pair of evaporators 28A, 28B due to a difference in the amounts of heat generated by the plural heat generating bodies 22A, 22B, the pressure is released from the evaporator at higher internal pressure to the evaporator at lower internal pressure through the bypass pipe 36.

This enables a difference in the amount of coolant supplied to the pair of evaporators 28A, 28B to be suppressed, even when the amounts of heat generated by the plural heat generating bodies 22A, 22B differ. This enables the cooling performance for the plural heat generating bodies 22A, 22B to be improved since the plural heat generating bodies 22A, 22B can each be cooled effectively.

Moreover, since internal pressure differences between the pair of evaporators 28A, 28B can be eliminated using a simple configuration in which the bypass pipe 36 has been added, a reduction in cost can be achieved.

The pair of evaporators 28A, 28B are mutually independent. The plural heat generating bodies 22A, 22B and other installed components can therefore be mounted to the substrate 21 with high efficiency due to being able to suppress limitations to the placement positions of the plural heat generating bodies 22A, 22B.

Note that the cooling airflow W is supplied to the condenser 26 as an example of an external fluid. However, an external fluid other than the cooling airflow W may be supplied to the condenser 26.

### Second Exemplary Embodiment

Explanation next follows regarding a second exemplary embodiment of technology disclosed herein.

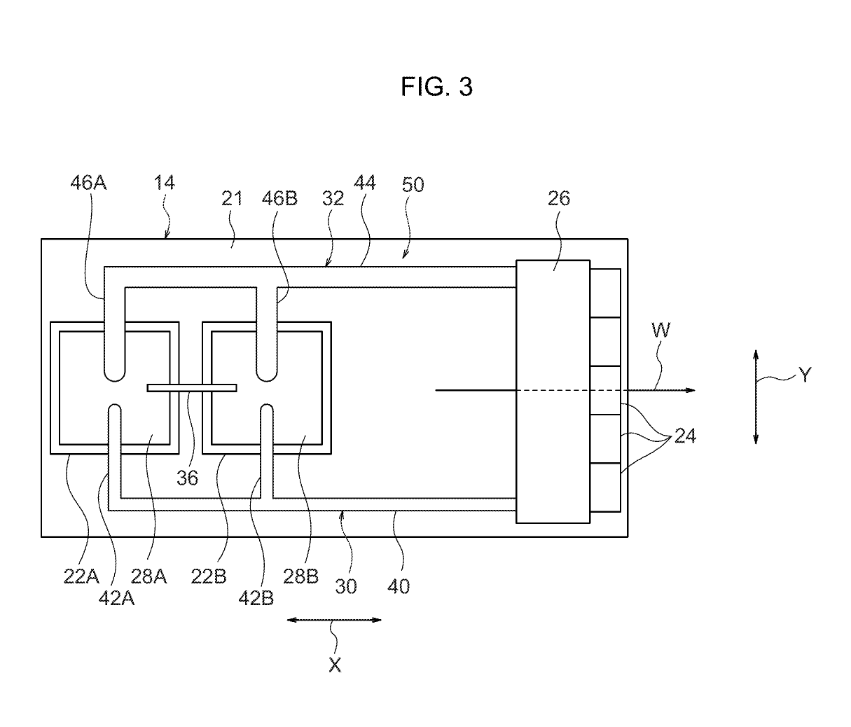

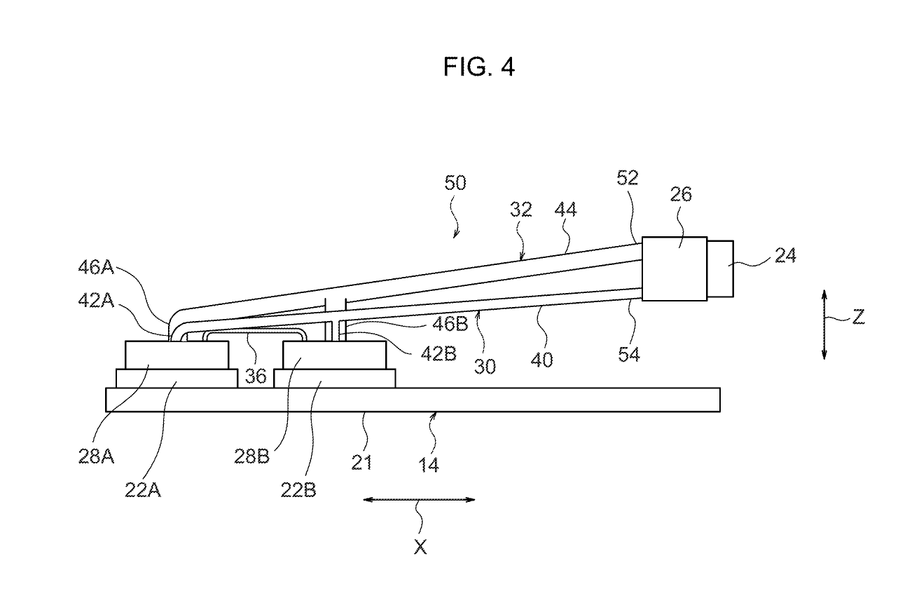

In a cooling system 50 according to a second exemplary embodiment illustrated in FIG. 3 and FIG. 4, configuration has been modified as follows from that of the cooling system 20 according to the first exemplary embodiment described above (see FIG. 2).

The circulation pump 34 described above (see FIG. 2) has been omitted from the cooling system 50 according to the second exemplary embodiment. Moreover, as illustrated in FIG. 4, the condenser 26 is disposed at a position at which the vertical height (in a Z-direction) is higher than that of the pair of evaporators 28A, 28B. The feed pipe main body 40 and the return pipe main body 44 are inclined with respect to the horizontal direction (X-direction) so as to approach the vertical direction upper side on progression toward the condenser 26 side. A connecting portion 52 between the return pipe 32 and the condenser 26 is disposed at a position higher than the vertical direction height of a connecting portion 54 between the feed pipe 30 and the condenser 26.

In the cooling system 50 according to the second exemplary embodiment, the coolant condensed by the condenser 26 is supplied to the pair of evaporators 28A, 28B through the feed pipe 30 using gravity. Moreover, the coolant vaporized by the pair of evaporators 28A, 28B is returned to the condenser 26 through the return pipe 32.

Thus likewise in the cooling system 50 according to the second exemplary embodiment, pressure is released from the evaporator at higher internal pressure to the evaporator at lower internal pressure through the bypass pipe 36 in cases in which a difference arises in the internal pressures between the pair of evaporators 28A, 28B.

This enables differences to be suppressed in the amount of coolant supplied to the pair of evaporators 28A, 28B even in cases in which the amounts of heat generated by the plural heat generating bodies 22A, 22B differ. As a result, effective cooling of the respective plural heat generating bodies 22A, 22B can be performed, thereby enabling cooling performance to be improved for plural heat generating bodies 22A, 22B.

Moreover, in the cooling system 50 according to the second exemplary embodiment, the circulation pump is unnecessary, enabling a reduction in cost to be achieved.

### Third Exemplary Embodiment

Explanation next follows regarding a third exemplary embodiment of technology disclosed herein.

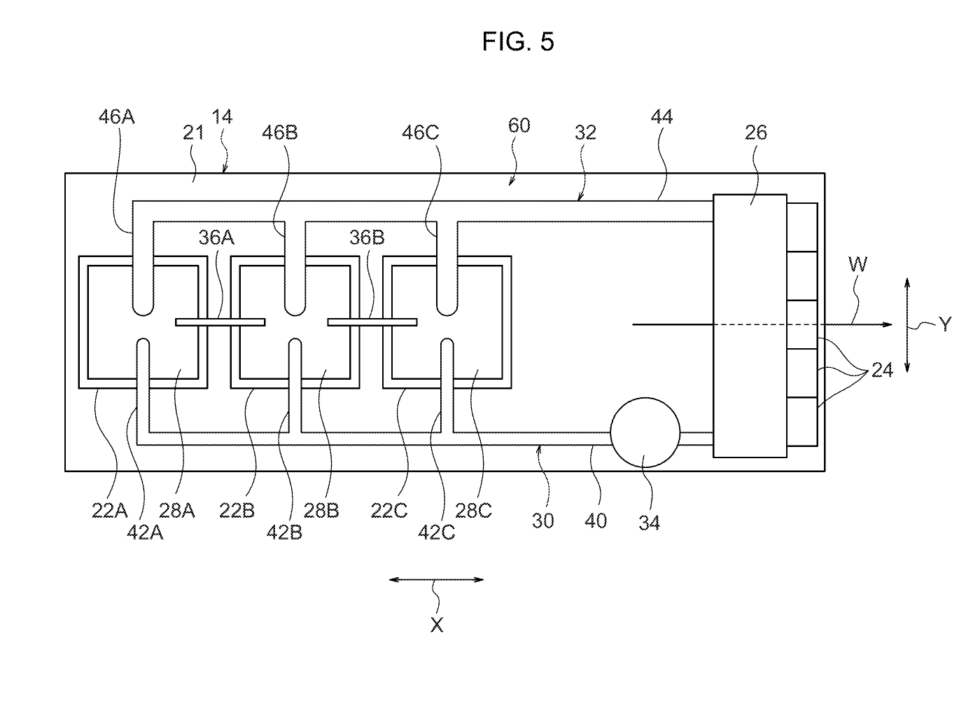

In a cooling system 60 according to a third exemplary embodiment illustrated in FIG. 5, configuration has been modified as follows from that of the cooling system 20 according to the first exemplary embodiment (see FIG. 2).

In the cooling system 60 according to the third exemplary embodiment, three heat generating bodies 22A to 22C are employed as an example. The three heat generating bodies 22A to 22C are disposed in a row in a specific direction along the substrate 21 (as an example, along the X-direction, which is the length direction of the substrate 21). Moreover, in the cooling system 60 according to the third exemplary embodiment, three evaporators 28A to 28C are employed corresponding to the three heat generating bodies 22A to 22C.

The three evaporators 28A to 28C are examples of heat receiving sections (heat receiving devices) in which a coolant absorbs heat that has been generated by the respective heat generating bodies, and are mutually independent. The three evaporators 28A to 28C are fixed above the respective plural heat generating bodies 22A to 22C, and are in thermal contact with the respective plural heat generating bodies 22A to 22C. The three evaporators 28A to 28C are configured similarly to the evaporators 28A, 28B of the first exemplary embodiment described above, and are configured similarly to one another.

The feed pipe 30 includes three connection pipes 42A to 42C. One end of each of the connecting pipes 42A to 42C is connected to the feed pipe main body 40, and the other end of the each of the connecting pipes 42A to 42C is connected to the top wall portion of the respective evaporator 28A to 28C.

Similarly, the return pipe 32 includes three connecting pipes 46A to 46C. One end of each of the connecting pipes 46A to 46C is connected to the return pipe main body 44, and the other end of the connecting pipes 46A to 46C is connected to the top wall portion of the respective evaporators 28A to 28C. The feed pipe 30 and the return pipe 32 connect the three evaporators 28A to 28C to the condenser 26 in parallel.

In the cooling system 60 according to the third exemplary embodiment, a pair of bypass pipes 36A, 36B are employed. The pair of bypass pipes 36A,36B are examples of bypass sections. One of the bypass pipes, the bypass pipe 36A, couples the evaporator 28A disposed at one end side to the central evaporator 28B. The other bypass pipe 36B couples the evaporator 28C disposed at the other end side to the central evaporator 28B.

Thus, likewise in the cooling system 60 according to the third exemplary embodiment, pressure is released from an evaporator at higher internal pressure to an evaporator at lower internal pressure through either of the bypass pipes 36A, 36B when differences arise in the internal pressure of the plural evaporators 28A to 28C.

This thereby enables differences in the amounts of coolant supplied to the plural evaporators 28A to 28C to be suppressed from arising even when the amounts of heat generated by the plural heat generating bodies 22A to 22C differ. This enables each of the plural heat generating bodies 22A to 22C to be cooled effectively, thereby enabling cooling performance for the plural heat generating bodies 22A to 22C to be improved.

In the cooling system 60 according to the third exemplary embodiment, the bypass pipes 36A, 36B are respectively coupled to neighboring evaporators out of the plural evaporators 28A to 28C. Connecting structures by the bypass pipes 36A, 36B can thus be simplified, since a short length is sufficient for each of the bypass pipes 36A, 36B.

The cooling system 60 of the third exemplary embodiment may be configured such that the circulation pump is omitted, similarly to in the second exemplary embodiment described above.

The evaporators 28A to 28C may each be respectively coupled to the two other evaporators through respective bypass pipes. Namely, in addition to the bypass pipes 36A, 36B coupling the evaporators 28A, 28B together and coupling the evaporators 28B, 28C together, the evaporators 28A, 28C may be coupled together by a bypass pipe. In such a configuration, the evaporators 28A, 28C are each coupled to two other evaporators through respective bypass pipes. Differences in internal pressure between the plural evaporators 28A to 28C can accordingly be more smoothly eliminated better than in cases in which the neighboring evaporators 28A, 28B and evaporators 28B, 28C are coupled together through respective bypass pipes 36A, 36B, as described above.

### Fourth Exemplary Embodiment

Explanation next follows regarding a fourth exemplary embodiment of technology disclosed herein.

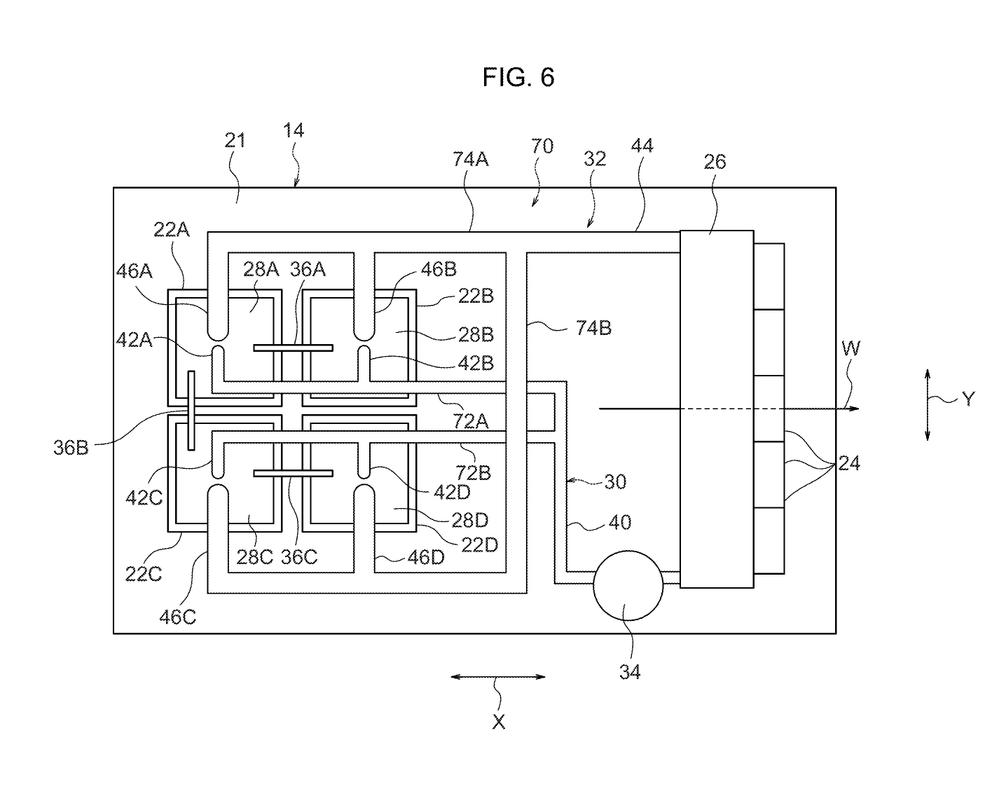

The configuration of a cooling system 70 according to the fourth exemplary embodiment illustrated in FIG. 6 is modified as follows from that of the cooling system 20 according to the first exemplary embodiment described above (see FIG. 2).

In the cooling system 70 according to the fourth exemplary embodiment, four heat generating bodies 22A to 22D are employed as an example. The four heat generating bodies 22A to 22D are arrayed in two directions, the length direction (X-direction) and the width direction (Y-direction) of the substrate 21, as an example. In the cooling system 70 according to the fourth exemplary embodiment, four evaporators 28A to 28D are employed corresponding to four heat generating bodies 22A to 22D.

The four evaporators 28A to 28D are examples of heat receiving sections (heat receiving devices) in which heat generated by respective heat generating bodies is absorbed by a coolant, and are mutually independent. The four evaporators 28A to 28D are fixed above the respective plural heat generating bodies 22A to 22D, and are in thermal contact with the respective plural heat generating bodies 22A to 22D. The four evaporators 28A to 28D are configured similarly to the evaporators 28A, 28B of the first exemplary embodiment described above, and are configured similarly to one another.

The feed pipe 30 includes a feed pipe main body 40 that is connected to a condenser 26, and a pair of feed pipe branch portions 72A, 72B that branch out from the feed pipe main body 40. A pair of connecting pipes 42A, 42B are provided at the distal end side of the one feed pipe branch portions 72A, and a pair of connecting pipes 42C, 42D are provided at the distal end side of the other feed pipe branch portion 72B. A distal end portion of each of the connecting pipes 42A to 42D is connected to respective top wall portions of the evaporators 28A to 28D.

Similarly, the return pipe 32 includes a return pipe main body 44 connected to the condenser 26, and a pair of return pipe branch portions 74A, 74B that branch out from the return pipe main body 44. A pair of connecting pipes 46A, 46B are provided at a distal end side of the one return pipe branch portions 74A, and a pair of connecting pipes 46C, 46D are provided to the distal end side of the other return pipe branch portion 74B. A distal end portion of each of the connecting pipes 46A to 46D is connected to a top wall portion of the respective evaporator 28A to 28D. The four evaporators 28A to 28D are thereby connected in parallel to the condenser 26 by the feed pipe 30 and the return pipe 32.

Moreover, three bypass pipes 36A to 36C are employed in the cooling system 70 according to the fourth exemplary embodiment. The three bypass pipes 36A to 36C are examples of bypass sections. The bypass pipe 36A couples the neighboring evaporators 28A, 28B together, and the bypass pipe 36B couples the neighboring evaporators 28A, 28C together. Moreover, the bypass pipe 36C couples the neighboring evaporators 28C, 28D together.

Thus likewise in the cooling system 70 according to the fourth exemplary embodiment, pressure can be released from an evaporator at higher internal pressure to an evaporator at lower internal pressure through one of the bypass pipes 36A to 36C when a difference in internal pressure arises between the plural evaporators 28A to 28D.

This thereby enables differences in the amounts of coolant supplied to the plural evaporators 28A to 28D to be suppressed from arising even when the amounts of heat generated by the plural evaporators 28A to 28D differ. This thereby enables effective cooling of the plural respective heat generating bodies 22A to 22D to be performed, thereby enabling cooling performance to be improved for plural heat generating bodies 22A to 22D.

Moreover, in the cooling system 70 according to the fourth exemplary embodiment, each of the bypass pipes 36A to 36C are respectively coupled to neighboring evaporators from out of the plural evaporators 28A to 28D. Connecting structures by the bypass pipes 36A to 36C can thereby be simplified, since a short length is sufficient for each of the bypass pipes 36A to 36C.

In the fourth exemplary embodiment, the cooling system 70 may be configured such that the circulation pipe is omitted, similar to in the second exemplary embodiment described above.

Moreover, the evaporator 28B and the evaporator 28D may be coupled together through a bypass pipe. Adopting such a configuration enables differences in the internal pressure of the plural evaporators 28A to 28D to be eliminated more smoothly since all of the neighboring evaporators out of the plural evaporators 28A to 28D are coupled through the bypass pipes.

Moreover, in the fourth exemplary embodiment, the number of the plural evaporators may be five or more. In such cases, at least one evaporator out of the plural evaporators may be coupled by respective bypass pipes to at least two other evaporators out of the plural evaporators.

### Fifth Exemplary Embodiment

Explanation next follows regarding a fifth exemplary embodiment of technology disclosed herein.

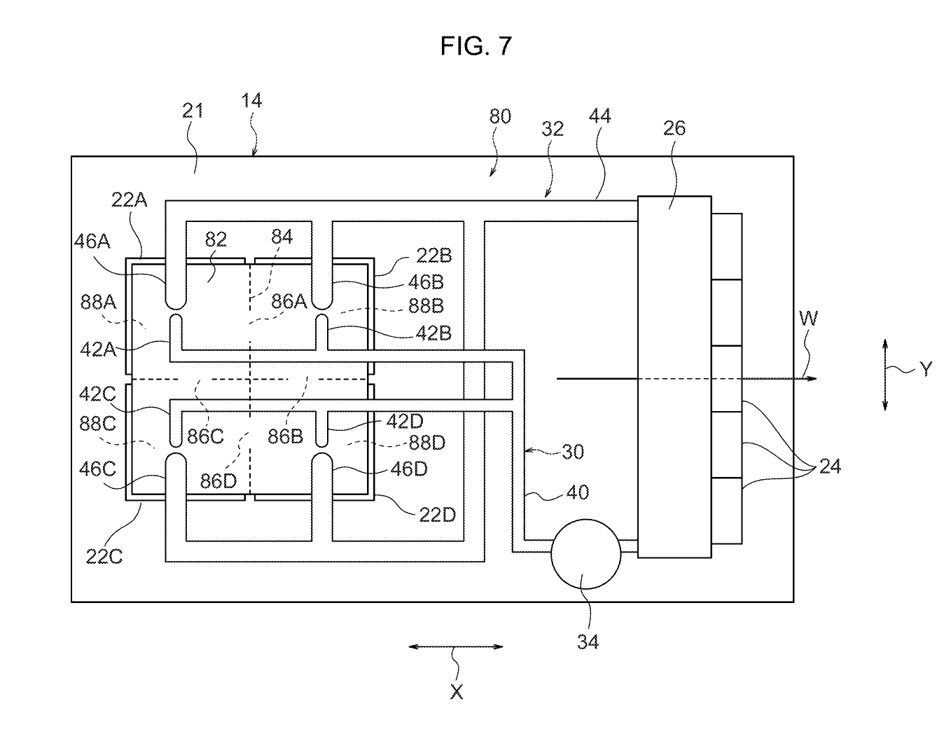

In a cooling system 80 according to the fifth exemplary embodiment illustrated in FIG. 7, configuration is modified as follows from that of the cooling system 70 according to the fourth exemplary embodiment (see FIG. 6).

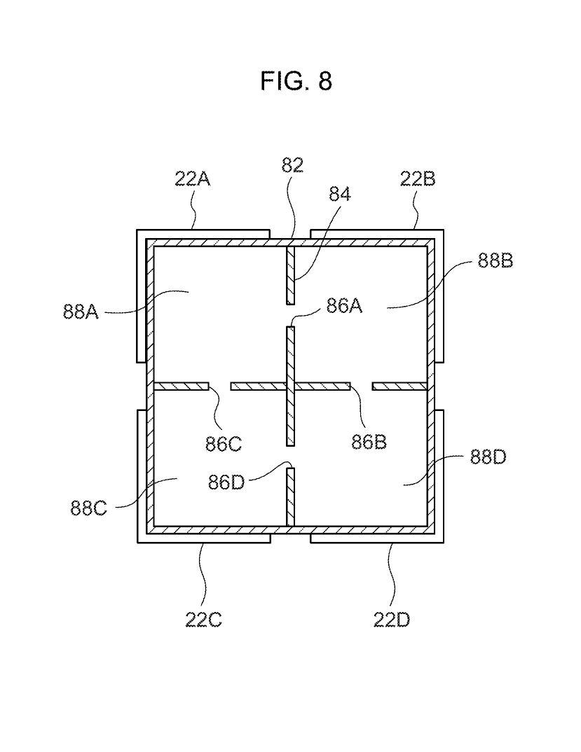

A single evaporator 82 is employed in the cooling system 80 according to the fifth exemplary embodiment. The evaporator is an example of a heat receiving device. As illustrated in FIG. 8, a partitioning wall 84 that is cross shaped in plan view is provided inside the evaporator 82. Four evaporator chambers 88A to 88D are thereby formed inside the evaporator 82, divided by the partitioning wall 84.

The evaporator chambers 88A to 88D are examples of heat receiving sections (heat receiving chambers) in which heat generated by respective heat generating bodies is absorbed by a coolant. The plural evaporator chambers 88A to 88D are provided above plural heat generating bodies 22A to 22D, respectively, and are in thermal contact with the plural heat generating bodies 22A to 22D, respectively. The four evaporator chambers 88A to 88D are configured similarly to one another. When liquefied coolant is supplied to the respective evaporation chambers, the coolant in the evaporator chambers 88A to 88D is vaporized by heat generated by the heat generating bodies 22A to 22D.

Moreover, plural opening portions 86A to 86D are provided in the partitioning wall 84. The opening portion 86A places the neighboring evaporation chambers 88A, 88B in communication with each other, and the opening portion 86B places the neighboring evaporation chambers 88B, 88D in communication with each other. Moreover, the opening portion 86C places the neighboring evaporation chambers 88A, 88C in communication with each other, and the opening portion 86D places the neighboring evaporation chambers 88C, 88D in communication with each other. The opening portions 86A to 86D are examples of bypass sections.

As illustrated in FIG. 7, distal end portions of each of connecting pipes 42A to 42D provided to a feed pipe 30, and distal end portions of each of connecting pipes 46A to 46D provided to a return pipe 32, are respectively connected to top wall portions of the evaporator chambers 88A to 88D. The feed pipe 30 and the return pipe 32 connect the four evaporator chambers 88A to 88D to the condenser 26 in parallel.

In the cooling system 80 according to the fifth exemplary embodiment, neighboring evaporation chambers out of the plural evaporation chambers 88A to 88D are coupled together (placed in communication) by the opening portions 86A to 86D. Accordingly, pressure is released from an evaporation chamber at higher internal pressure to an evaporation chamber at lower internal pressure through one of the opening portions 86A to 86D, even when differences arise in the internal pressures of the plural evaporator chambers 88A to 88D due to differences in the amounts of heat generated by the plural heat generating bodies 22A to 22D.

This enables differences in the amount of coolant supplied to the plural evaporator chambers 88A to 88D to be suppressed from arising even when the amounts of heat generated by the plural heat generating bodies 22A to 22D differ. As a result, effective cooling of the respective plural heat generating bodies 22A to 22D can be performed, thus enabling cooling performance to be improved for plural heat generating bodies 22A to 22D.

The cooling system 80 according to the fifth exemplary embodiment enables the plural heat generating bodies 22A to 22D to be cooled by the single evaporator 82. A reduction in the number of components is accordingly enabled, thus enabling a reduction in cost to be achieved.

Moreover, each of the evaporator chambers 88A to 88D is in communication with two other evaporator chambers, enabling differences in the internal pressures of the plural evaporator chambers 88A to 88D to be more smoothly eliminated.

Moreover, opening portions 86A to 86D formed in the partitioning wall 84 are employed to couple the four evaporator chambers 88A to 88D together. Accordingly, a reduction in cost of the evaporator 82 can be achieved since, for example, the internal structure of the evaporator 82 can be simplified compared to cases in which bypass pipes are employed

In the fifth exemplary embodiment, the cooling system 80 may omit the circulation pump similarly to in the second exemplary embodiment described above.

Moreover, in the fifth exemplary embodiment, the number of the plural evaporation chambers may be five or more. In such cases, at least one evaporation chamber out of the plural evaporation chambers may be coupled to at least two other evaporation chambers out of the plural evaporation chambers through respective opening portions.

Moreover, in the fifth exemplary embodiment, configuration may be made such that not all of the neighboring heat receiving sections out of the plural evaporator chambers 88A to 88D are coupled together through the opening portions 86A to 86D, and some of the neighboring heat receiving sections out of the plural evaporator chambers 88A to 88D are not in communication with each other.

### Sixth Exemplary Embodiment

Explanation next follows regarding a sixth exemplary embodiment according to technology disclosed herein.

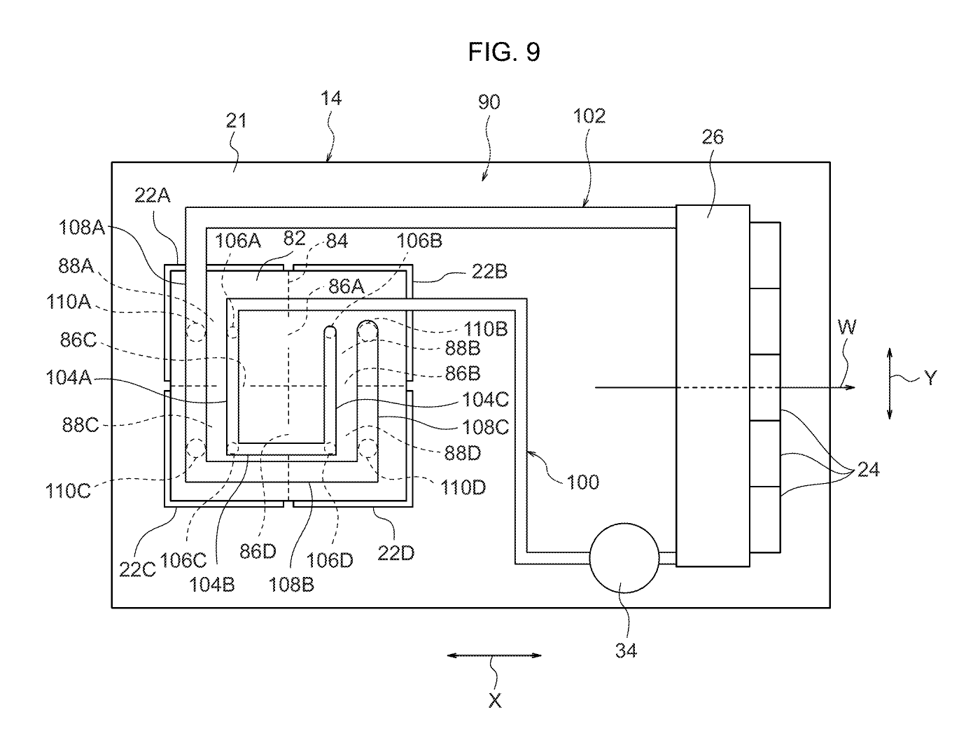

Configuration of a cooling system 90 according to a sixth exemplary embodiment illustrated in FIG. 9 is modified as follows from that of the cooling system 80 according to the fifth exemplary embodiment described above (see FIG. 7 and FIG. 8).

In the cooling system 90 according to the sixth exemplary embodiment, a feed pipe 100 and a return pipe 102 are employed. The feed pipe 100 and the return pipe 102 each has a continuous shape with no branches (a single line shape).

Namely, one end of the feed pipe 100 is connected to an opening in a condenser 26. Moreover, plural bend portions 104A to 104C are formed to another end side of the feed pipe 100.

The bend portion 104A extends along the width direction of a substrate 21, and is provided straddling between neighboring evaporator chamber 88A and evaporation chamber 88C. The bend portion 104B extends along the length direction of the substrate 21, and is provided straddling between neighboring evaporation chamber 88C and evaporation chamber 88D. The bend portion 104C extends along the width direction of the substrate 21, and is provided straddling between neighboring evaporation chamber 88B and evaporation chamber 88D.

One end of the bend portion 104A is connected to the evaporator chamber 88A through a connecting portion 106A, and another end of the bend portion 104A is connected to the evaporation chamber 88C through a connecting portion 106C. Similarly, one end of the bend portion 104C is connected to the evaporation chamber 88B through a connecting portion 106B, and another end of the bend portion 104C is connected to the evaporation chamber 88D through the connecting portion 106D. The feed pipe 100 is thus connected to the plural evaporation chambers 88A to 88D in sequence on progression from one length direction side toward the other length direction side.

One end of the return pipe 102 is connected to an inlet of the condenser 26. Moreover, the plural bend portions 108A to 108C are formed to another end side of the return pipe 102.

The bend portion 108A extends along the width direction of the substrate 21, and is provided straddling between the neighboring evaporator chamber 88A and evaporation chamber 88C. The bend portion 108B extends along the length direction of the substrate 21, and is provided straddling between the neighboring evaporation chamber 88C and evaporation chamber 88D. The bend portion 108C extends along the width direction of the substrate 21, and is provided straddling between the neighboring evaporation chamber 88B and evaporation chamber 88D.

One end of the bend portion 108A is connected to the evaporator chamber 88A through a connecting portion 110A, and another end of the bend portion 108A is connected to the evaporation chamber 88C through a connecting portion 110C. Similarly, one end of the bend portion 108C is connected to the evaporation chamber 88B through a connecting portion 110B, and another end of the bend portion 108C is connected to the evaporation chamber 88D through a connecting portion 110D. The return pipe 102 is thereby connected to the plural evaporation chambers 88A to 88D in sequence on progression from one side in the length direction to the other side in the length direction. The four evaporation chambers 88A to 88D are connected in parallel to the condenser 26 by the feed pipe 100 and the return pipe 102.

Likewise in the cooling system 90 according to the sixth exemplary embodiment, pressure is released from an evaporation chamber at higher internal pressure to an evaporation chamber at lower internal pressure through one of the opening portions 86A to 86D when a difference arises in the internal pressures of the plural evaporation chambers 88A to 88D.

This enables a difference in the amount of coolant supplied to the pair of evaporators 88A, 88B to be suppressed, even when the amounts of heat generated by the plural heat generating bodies 22A, 22B differ. This enables the cooling performance for the plural heat generating bodies 22A, 22B to be improved since the plural heat generating bodies 22A, 22B can each be cooled effectively.

Moreover, the feed pipe 100 and the return pipe 102 are connected to each of the plural evaporation chambers in sequence on progression from one length direction side to the other length direction side. This enables the configurations of the feed pipe 100 and the return pipe 102 to be simplified compared to cases in which the feed pipe 100 and the return pipe 102 each include a branch portion.

In the sixth exemplary embodiment, the cooling system 90 may be configured by omitting the circulation pump similarly to in the second exemplary embodiment described above.

The number of the plural evaporation chambers in the sixth exemplary embodiment may be five or more. In such cases, at least one evaporation chamber out of the plural evaporation chambers may be coupled to at least two other evaporation chambers out of the plural evaporation chambers through respective opening portions.

In the sixth exemplary embodiment, plural independent evaporation chambers 28A to 28D may be employed instead of the plural evaporation chambers 88A to 88D, as in the fourth exemplary embodiment described above. In such cases, bypass pipes may be employed to couple the plural evaporation chambers 28A to 28D together.

The cooling systems of the first exemplary embodiment to the sixth exemplary embodiment above include a condenser that condenses vaporized coolant by exchanging heat with an external fluid, and an evaporator that vaporizes coolant using heat generated by a heat generating body, and is configured as a system that utilizes latent heat.

However, in the first exemplary embodiment to the sixth exemplary embodiment above, the cooling system may include a heat dissipation section that dissipates heat from the coolant by exchanging heat with an external fluid, and a heat receiving section in which the coolant absorbs heat generated by a heat generating body, and may be configured as a system that utilizes sensible heat.

The cooling system of the present disclosure enables cooling performance to be improved for plural heat generating bodies.

Although examples of technology disclosed herein have been explained above, technology disclosed herein is not limited to the above descriptions, and it is obvious that in addition to the descriptions above, various modifications may be implemented within a range not exceeding the spirit of those descriptions.

All cited documents, patent applications and technical standards mentioned in the present specification are incorporated by reference in the present specification to the same extent as if the individual cited documents, patent applications and technical standards were specifically and individually incorporated by reference in the present specification.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling system, comprising:
a heat dissipating section that dissipates heat from a coolant by exchanging heat with an external fluid;
a plurality of heat receiving sections that are connected in parallel to the heat dissipating section, and in which heat generated by respective heat generating bodies is absorbed by the coolant; and
a bypass section that couples at least one of the heat receiving sections out of the plurality of heat receiving sections to another heat receiving section.

2. The cooling system of claim 1, wherein
the bypass section is a bypass pipe.

3. The cooling system of claim 1, wherein
the plurality of heat receiving sections is a plurality of mutually independent heat receiving devices.

4. The cooling system of claim 1, wherein:
the plurality of heat receiving sections is formed by a plurality of heat receiving chambers divided by a partitioning wall formed inside a heat receiving device; and
the partitioning wall is provided with an opening portion serving as the bypass section.

5. The cooling system of claim 1, wherein:
the plurality of heat receiving sections includes three or more heat receiving sections; and
at least one heat receiving section out of the plurality of heat receiving sections is coupled to at least two other heat receiving sections out of the plurality of heat receiving sections through the bypass section.

6. The cooling system of claim 1, wherein
the bypass section couples together at least neighboring heat receiving sections out of the plurality of heat receiving sections.

7. The cooling system of claim 1, wherein:
the plurality of heat receiving sections is connected in parallel to the heat dissipating section through a feed pipe and a return pipe;
the feed pipe includes a feed pipe main body connected to the heat dissipating section, and a plurality of feed pipe branch portions that branch out from the feed pipe main body and that are respectively connected to the plurality of heat receiving sections; and
the return pipe includes a return pipe main body connected to the heat dissipating section, and a plurality of return pipe branch portions that branch out from the return pipe main body and that are respectively connected to the plurality of heat receiving sections.

8. The cooling system of claim 1, wherein:
the plurality of heat receiving sections are arrayed along two directions; and
the feed pipe and the return pipe are connected to each of the plurality of heat receiving sections in sequence on progression from one side in a length direction to another side in the length direction.

9. The cooling system of claim 1, wherein
a circulation pump is provided at the feed pipe.

10. The cooling system of claim 1, wherein
the heat dissipating section is disposed at a high position that is higher in a vertical direction than the plurality of heat receiving sections.

11. An electronic device comprising:
a plurality of heat generating bodies; and
the cooling system of claim 1.
